(19) United States
(12) Patent Application Publication
(10) Pub. No.: US 2014/0264721 A1
(43) Pub. Date: Sep. 18, 2014

(54) ISOLATION STRUCTURE IN A SEMICONDUCTOR DEVICE PROCESSES AND STRUCTURES

(71) Applicant: MACRONIX INTERNATIONAL CO., LTD., Hsinchu (TW)

(72) Inventor: Guo-Yu LAN, Taichung City (TW)

(21) Appl. No.: 14/049,973

(22) Filed: Oct. 9, 2013

Related U.S. Application Data
(60) Provisional application No. 61/776,922, filed on Mar. 12, 2013.

(51) Int. Cl. H01L 29/06; H01L 21/762

(52) U.S. Cl. CPC H01L 29/0649; H01L 21/76224
USPC 257/506; 438/425

(57) ABSTRACT

Substantially planar or even layers in semiconductor trenches allow for even distribution of subsequent layers in semiconductor processing and reduce divots in semiconductor device layers. A semiconductor device may include an isolation structure formed in a trench. The isolation structure may have a cover oxide layer and a base oxide layer holding the cover oxide layer. The top surface of the isolation structure is substantially planar. An oxidation process may substantially eliminate nitrogen from a top portion of the isolation structure, resulting in a balanced etch rate in the top portion and a substantially even isolation structure top surface.

### RELATED APPLICATIONS

This application is a non-provisional and claims priority to U.S. Patent Application No. 61/776,922 filed Mar. 12, 2013 entitled “Isolation structure in a semiconductor device and method for manufacturing thereof,” which is incorporated herein by reference for all purposes.

### TECHNICAL FIELD

This disclosure relates to semiconductor devices and, more specifically, relates to substantially planar isolation structures in semiconductor devices.

### BACKGROUND

Spin-on glass (SOG) film is a liquid glass film applied to fill crevices in semiconductor fabrication processes. SOG film is useful for filling trenches in semiconductor devices and is widely used in the semiconductor manufacturing processes. Due to the liquid nature of the SOG concave structures often form at various layers made of SOG film. In other words, a top surface of the SOG film layers in semiconductor trenches is often uneven, having a lower surface toward the center of the trench and a higher surface toward the trench edges. In addition, SOG film contains nitrogen and has a relatively high wet etch rate. Uneven layers in semiconductor trenches and unmatched wet etch rates can cause problems in semiconductor processing, such as formation of divots or other uneven layers in subsequent processing steps.

### SUMMARY

A semiconductor device may include a trench formed in a semiconductor substrate and an isolation structure formed in the trench. The isolation structure may have a cover oxide layer and a base oxide layer. The base oxide layer may hold the cover oxide layer, and a top surface of the isolation structure is substantially planar.

According to another aspect, a semiconductor device may include a trench formed in a semiconductor substrate and an isolation structure formed in the trench. The isolation structure is defined by a top surface, two side surfaces, and a bottom surface. The top surface of the isolation structure is at a first depth, the bottom surface of the isolation structure is at a second depth, and a third depth is defined between the first and second depths. Isolation structure nitrogen content between the first and third depth is in a range of 5×10¹⁹ to 1×10²⁰ atoms/cm³, and isolation structure nitrogen content from the third depth to the second depth increases with respect to depth.

According to another aspect, a method for manufacturing a semiconductor device may include forming an isolation structure in a trench of a semiconductor substrate by applying an oxidation process to a cover top surface of a cover oxide layer and at least a portion of a base top surface a base oxide layer. The cover oxide layer and the base oxide layer comprise the isolation structure. The isolation structure is defined by a top surface, two side surfaces, and a bottom surface, and the oxidation process substantially eliminates nitrogen from a top portion of the isolation structure proximate to the top surface.

### BRIEF DESCRIPTION OF THE DRAWINGS

FIGS. 1A, 1B, and 1C are schematic diagrams illustrating a cross sections semiconductor devices;

FIG. 2 is a flow diagram illustrating a process for forming an isolation structure of a semiconductor device, in accordance with the present disclosure;

FIGS. 3A, 3B, 3C, and 3D are schematic diagrams illustrating cross sections of semiconductor devices, in accordance with the present disclosure;

FIG. 4A is a schematic diagram illustrating an isolation structure of a semiconductor device, in accordance with the present disclosure;

FIG. 4B is a graphical diagram illustrating nitrogen concentration for the isolation structure of FIG. 4A, in accordance with the present disclosure;

FIG. 5 is a schematic diagram illustrating a cross section of an isolation structure of a semiconductor device, in accordance with the present disclosure;

FIG. 6 is a schematic diagram illustrating a cross section of an isolation structure of a semiconductor device, in accordance with the present disclosure; and

FIGS. 7A and 7B are schematic diagrams illustrating oxidation processes, in accordance with the present disclosure.

### DETAILED DESCRIPTION

FIGS. 1A, 1B, and 1C are schematic diagrams illustrating cross sections semiconductor devices. FIG. 1A shows a semiconductor device having a trench 101 with a pad oxide layer 107 conformal to the trench 101. A base oxide layer 103 is formed within the pad oxide layer 107 of the trench 101. In an embodiment, the base oxide layer 103 is spin-on glass (SOG) film. A densification process is performed on the base oxide layer 103 to cure the base oxide layer 103, resulting in an base oxide layer 103. Silicon nitride structures 105 are adjacent to sidewalls of the base oxide layer 103. As shown in FIG. 1A, due to the liquid nature of SOG film, the top surface 109 of the base oxide layer 103 is a concave shape.

FIG. 1B shows a cover oxide layer 111 deposited on the base oxide layer 103. In an embodiment, the cover oxide layer 111 is a chemical vapor deposition (CVD) oxide layer. A planarizing process is used on the cover oxide layer 111 and the base oxide layer 103. For example, a chemical mechanical polish (CMP) process may be used to planarize the cover oxide layer 111 and the base oxide layer 103.

FIG. 1C shows that a silicon nitride process has been performed, such as hot phosphoric acid application, removing the silicon nitride structures 105 and forming a shallow trench isolation (STI) structure 117. However, because the base oxide layer 103 has a higher wet etching rate (WER) than the cover oxide layer 111, the base oxide layer 103 will etch at a faster rate than the cover oxide layer 111. Thus, the base oxide layer 103 and the cover oxide layer 111 will not etch evenly, and divots 115 will form in the cover oxide layer 103 at the top surface of the STI structure 117.

The higher wet etching rate of the base oxide layer 103 is a result of the base oxide layer 103 having a higher concentration of nitrogen (N) as compared with the cover oxide layer 111. The nitrogen concentration 113 in the STI structure 117 increases toward the bottom of the STI structure 117, but is still present in the base oxide layer 103 at the top surface of the STI structure.

FIG. 2 is a flow diagram illustrating a process for forming an isolation structure of a semiconductor device. The process may include applying an oxidation process (action 210) to form an isolation structure in a trench of a semiconductor substrate. The oxidation process (action 210) may be applied to a top surface of the isolation structure. Specifically, the oxidation process (action 210) may be applied to a cover oxide layer and at least a portion of a top surface of a base oxide layer making up the top surface of the isolation structure. In an embodiment, the cover oxide layer is a CVD oxide layer, and the base oxide layer is an SOG oxide layer. The oxidation process (action 210) substantially eliminates nitrogen from a top portion of the isolation structure proximate to the top surface. In an embodiment, the oxidation process (action 210) results in the nitrogen content in the top portion of the isolation structure in a range of 5×10¹⁹ to 1×10²⁰ atoms/cm³. In another embodiment, the oxidation process (action 210) results in the nitrogen content in a bottom portion of the isolation structure in a range of 1×10²¹ to 4×10²¹ atoms/cm³.

The process may further comprise forming the base oxide layer (action 202) in a trench of a semiconductor substrate. The base oxide layer may be defined by two base side surfaces, a base top surface, and a base bottom surface. A portion of the base top surface may be a concave shape. For example, in an embodiment, the base oxide layer is a spin-on glass (SOG) oxide film, and due to the liquid nature of SOG film, the top surface of the base oxide layer is a concave shape.

The process may further including curing the base oxide layer by performing a densification process on the base oxide layer material (action 204). The process may further include forming a cover oxide layer in the concave portion of the base oxide layer (action 206). In an embodiment, the cover oxide layer is a chemical vapor deposition (CVD) oxide film, and forming the cover oxide layer may include applying a chemical vapor deposition process to provide the cover oxide layer. The cover oxide layer may be defined by a cover top surface and a cover bottom surface.

The process may further include planarizing the cover oxide layer (action 208) prior to applying the oxidation process (action 210). The process may further include removing the silicon nitride material adjacent to the isolation structure using a wet etching process (action 212). In an embodiment, the top surface of the isolation structure after the wet etching is substantially planar because oxidation process (action 210) allows for the wet etching rate of the base oxide layer and the cover oxide layer to be substantially the same. Thus, in an embodiment, the wet etching process (action 212) includes removing the silicon nitride material and etching substantially evenly or at the same rate the cover oxide layer and the base oxide layer near the top surface of the isolation structure.

FIGS. 3A, 3B, 3C, and 3D are schematic diagrams illustrating cross sections of semiconductor devices throughout a semiconductor manufacturing process. FIG. 3A shows a semiconductor device in which a base oxide layer 103 has been formed within a pad oxide layer 107 of a trench 101 of a semiconductor substrate. The top surface of the base oxide layer 103 may be a concave shape. For example, in an embodiment, the base oxide layer 103 is a spin-on glass (SOG) oxide film, and, due to the liquid nature of SOG film, the top surface of the base oxide layer is a concave shape.

The base oxide layer 103 may be cured by performing a densification process on the base oxide layer material. A cover oxide layer 111 is formed over the base oxide layer 103, including formed in the concave portion of the base oxide layer 103. In an embodiment, the cover oxide layer 111 is a chemical vapor deposition (CVD) oxide film, and forming the cover oxide layer may include applying a chemical vapor deposition process to provide the cover oxide layer. The nitrogen concentration 113 in the base oxide layer 103 increases toward the bottom of the base oxide layer 103, but is still present in the base oxide layer 103 at the top surface.

FIG. 3B shows that the cover oxide layer 111 is planarized. Thus, the silicon nitride portions 105 and the cover oxide layer 111 are substantially planar and even.

FIG. 3C shows an oxidation process 110 being applied to the isolation structure. The oxidation process may be applied to a top surface of the isolation structure. Specifically, the oxidation process may be applied to the top surface of the cover oxide layer 111 and at least a portion of a top surface of a base oxide layer 103. The oxidation process 110 substantially eliminates nitrogen from a top portion of the base oxide layer 103. Thus, the nitrogen concentration 114 is more concentrated in the bottom of the base oxide layer 103 than prior to the oxidation process 110. In an embodiment, the oxidation process 110 results in the nitrogen content in the top portion of the isolation structure in a range of 5×10¹⁹ to 1×10²⁰ atoms/cm³. In another embodiment, the oxidation process 110 results in the nitrogen content in a bottom portion of the isolation structure in a range of 1×10²¹ to 4×10²¹ atoms/cm³.

FIG. 3D shows that the silicon nitride material 105 adjacent to the isolation structure 117 has been removed. In an embodiment, the silicon nitride material 105 is removed using a wet etching process.

In an embodiment, the top surface of the isolation structure 117 after the wet etching is substantially planar because oxidation process 110 allows for the wet etching rate of the base oxide layer 103 and the cover oxide layer 111 to be substantially the same. Thus, in an embodiment, the wet etching process includes removing the silicon nitride material and etching substantially evenly or at substantially the same rate the cover oxide layer 111 and the base oxide layer 103 near the top surface of the isolation structure 117.

FIG. 4A is a schematic diagram illustrating an isolation structure 117 formed in a trench 101 of a semiconductor device substrate. The isolation structure 117 includes a base oxide layer 103. The isolation structure 117 further includes a cover oxide layer 111. A top surface of the base oxide layer 103 has a concave portion, and the cover oxide layer 111 is formed in the concave portion of the base oxide layer 103.

In an embodiment, the isolation structure 117 has a nitrogen concentration 114 that increases with the depth of the isolation structure 117. For example, in an embodiment, at a first depth 119 at a top surface of the isolation structure 117, the nitrogen content is at a substantially negligible level (e.g., 0 to 5×10¹⁹ atoms/cm³). Preferably, the nitrogen content at the first depth is in a range of 5×10¹⁹ to 1×10²⁰ atoms/cm³. The bottom surface of the isolation structure 117 is at a second depth 123. In an embodiment, isolation structure nitrogen content at the second depth 123 is in a range of 1×10²¹ to 4×10²¹ atoms/cm³]. A trough 116 of the concave portion of the base oxide layer 103 is proximate to a third depth 121. In an embodiment, the isolation structure 117 nitrogen content 114 between the first and third depth is in a range of 1×10²⁰ to 1×10²¹ atoms/cm³, and the isolation structure nitrogen content 114 from the third depth to the second depth increases with respect to depth.

FIG. 4B is a graphical diagram illustrating nitrogen concentration 114 at various depths 119, 121, 123 for the isolation structure 117 of FIG. 4A. As shown in FIG. 4B, the nitrogen content 114 is at a substantially negligible level (e.g., 0 to 5×10¹⁹ atoms/cm³) between the first depth 119 and the third depth 121. The nitrogen content 114 increases dramatically between the third depth 121 and the second depth 123.

FIG. 5 is a schematic diagram illustrating a cross section of an isolation structure 117 formed in a trench 101 in a semiconductor device substrate 100. The isolation structure 117 is defined by a top surface 131, two side surfaces 133, and a bottom surface 135. The isolation structure may include a cover oxide layer 111 and a base oxide layer 103.

FIG. 6 is a schematic diagram further illustrating a cross section of the isolation structure 117. The base oxide layer 103 is defined by two base side surfaces 143, a base top surface 141, and a base bottom surface 145. The base top surface 141 may include a concave portion 144 and one or more even portions 146 extending from the sides of the concave portion 144. The cover oxide layer 111 is defined by a cover top surface 151 and a cover bottom surface 155. Further, the cover oxide layer 111 may be formed within the concave portion 144 of the base oxide layer 103. Thus, the top surface 131 of the isolation structure 117 may include the cover top surface 151 and at least a portion of the base top surface 146. In an embodiment, the top surface 131 of the isolation structure 117 is substantially planar.

In an embodiment, the top surface 131 of the isolation structure 117 is at a first depth 119, and the bottom surface 135 of the isolation structure 117 is at a second depth 123. In an embodiment, the isolation structure 117 nitrogen content 114 at the first depth 119 is substantially at a substantially negligible level (e.g., 0 to 5×10¹⁹ atoms/cm³). In an embodiment, the isolation structure 117 nitrogen content 114 at the first depth 119 is in a range of 5×10¹⁹ to 1×10²⁰ atoms/cm³. In an embodiment, the isolation structure 117 nitrogen content 114 at the second depth 123 is in a range of 1×10²¹ to 4×10²¹ atoms/cm³.

In an embodiment, a trough 116 of the concave portion 144 of the base oxide layer 103 is proximate to a third depth 121. The trough 116 is a deepest meeting point at which the base oxide layer 103 and cover oxide layer 111 of the isolation structure 117 are adjoined. The isolation structure 117 nitrogen content 114 between the first depth 119 and third depth 121 is in a range of 1×10²⁰ to 1×10²¹ atoms/cm³, and isolation structure 117 nitrogen content 114 from the third depth 121 to the second depth 123 increases with respect to depth.

Generally speaking, isolation structure 117 nitrogen content 114 between the first depth 119 and third depth 121 is in a range of 5×10¹⁹ to 1×10²⁰ atoms/cm³, and from the third depth 121 to the second depth 123 increases from a range of 1×10²⁰ to 1×10²¹ atoms/cm³ at the third depth 121 to a range of 1×10²¹ to 4×10²¹ atoms/cm³ at the second depth 123.

In an embodiment, the wet etching rate of a top portion 150 of the base oxide layer 103 is substantially the same as a wet etching rate of the cover oxide layer 111. When the etching rates are substantially the same, the top surface 131 of the isolation structure 117 is etched evenly, allowing for the top surface 131 to be substantially planar.

FIGS. 7A and 7B are schematic diagrams illustrating oxidation processes. FIG. 7A illustrates plasma oxidation processes. In an embodiment, the plasma includes ions, radicals, and electrons, including substantially the same amount of ions and electrons to maintain neutral properties. FIG. 7B illustrates radical oxidation processes. The oxide radical is produced in a low pressure, high temperature condition.

The low-temperature, oxidation processes used in the present disclosure may be plasma oxidation processes or radical oxidation processes. In an embodiment, the temperature of performing the plasma oxidation process or radical oxidation process is in a range of 200 to 500 degrees Celsius.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A semiconductor device, comprising:
a trench formed in a semiconductor substrate; and
an isolation structure formed in the trench, comprising:
a cover oxide layer, and
a base oxide layer,
wherein the base oxide layer holds the cover oxide layer, and wherein a top surface of the isolation structure is substantially planar.

2. The semiconductor device of claim 1, wherein the top surface of the isolation structure is at a first depth and wherein a bottom surface of the isolation structure is at a second depth, and wherein isolation structure nitrogen content at the first depth is at a substantially negligible level.

3. The semiconductor device of claim 1, wherein the isolation structure is defined by a top surface, two side surfaces, and a bottom surface, and
wherein the base oxide layer is defined by two base side surfaces, a base top surface, a base bottom surface, and
wherein the base top surface comprises a concave portion, and
wherein the cover oxide layer is defined by a cover top surface and a cover bottom surface, the cover oxide layer formed within the concave portion of the base oxide layer, and
wherein the top surface of the isolation structure comprises the cover top surface and at least a portion of the base top surface.

4. The semiconductor device of claim 3, wherein the top surface of the isolation structure is at a first depth, the bottom surface of the isolation structure is at a second depth, and a trough of the concave portion of the base oxide layer is proximate to a third depth, and
wherein isolation structure nitrogen content from the third depth to the second depth increases with respect to depth.

5. The semiconductor device of claim 3, wherein the base top surface further comprises two even portions extending from the concave portion, wherein the top surface of the isolation structure comprises the two even portions of the base top surface.

6. The semiconductor device of claim 1, wherein a wet etching rate of a top portion of the base oxide layer is substantially the same as a wet etching rate of the cover oxide layer.

7. A semiconductor device, comprising:
a trench formed in a semiconductor substrate; and
an isolation structure formed in the trench, the isolation structure defined by a top surface, two side surfaces, and a bottom surface, and
wherein the top surface of the isolation structure is at a first depth, the bottom surface of the isolation structure is at a second depth, and a third depth is defined between the first and second depths,
wherein isolation structure nitrogen content from the third depth to the second depth increases with respect to depth.

8. The semiconductor device of claim 7, wherein isolation nitrogen content from the third depth to the second depth increases.

9. The semiconductor device of claim 7, wherein the top surface of the isolation structure is substantially planar.

10. The semiconductor device of claim 7, wherein the third depth is proximate to a deepest meeting point at which a base oxide layer and cover oxide layer of the isolation structure are adjoined.

11. A method for manufacturing a semiconductor device, the method comprising:
forming an isolation structure in a trench of a semiconductor substrate by applying an oxidation process to a cover top surface of a cover oxide layer and at least a portion of a base top surface a base oxide layer, the cover oxide layer and the base oxide layer comprising the isolation structure,
wherein the isolation structure is defined by a top surface, two side surfaces, and a bottom surface, and wherein the oxidation process substantially eliminates nitrogen from a top portion of the isolation structure proximate to the top surface.

12. The method of claim 11, wherein the top surface of the isolation structure comprises the cover oxide layer top surface and the portion of the base top surface.

13. The method of claim 11, further comprising:
forming a base oxide layer in the trench, the base oxide layer defined by two base side surfaces, the base top surface, a base bottom surface, wherein the base top surface comprises a concave portion; and
forming a cover oxide layer in the concave portion of the base oxide layer, the cover oxide layer defined by the cover top surface and a cover bottom surface.

14. The method of claim 13, wherein forming the base oxide layer comprises:
using a spin-on-glass material to fill the trench; and
performing a densification process on the spin-on-glass material, thereby resulting in the concave portion of the base oxide layer.

15. The method of claim 13, further comprising applying a chemical vapor deposition process to provide the cover oxide layer.

16. The method of claim 15, further comprising:
planarizing the cover oxide layer prior to applying the oxidation process; and
removing a silicon nitride material adjacent to the isolation structure using a wet etching process,
wherein the top surface of the isolation structure after the wet etching is substantially planar.

17. The method of claim 11, wherein applying the oxidation process includes one of applying a plasma oxidation process and applying a radical oxidation process.
